(19) United States
(12) Patent Application Publication
(10) Pub. No.: US 2018/0018000 A1
(43) Pub. Date: Jan. 18, 2018

(54) INTEGRATED LIQUID COOLING OF A SERVER SYSTEM

(71) Applicant: Hewlett Packard Enterprise Development LP, Houston, TX (US)

(72) Inventors: Tahir Cader, Liberty Lake, WA (US); John P. Franz, Houston, TX (US); David A. Moore, Tomball, TX (US)

(21) Appl. No.: 15/546,050

(22) PCT Filed: Jan. 30, 2015
(86) PCT No.: PCT/US15/13981

§ 371 Date: Jul. 25, 2017

(51) Int. Cl. G06F 1/20; G05B 19/4099; H05K 7/20

(52) U.S. Cl. CPC G06F 1/20; B33Y 80/00; B29C 64/393; H05K 7/20772; H05K 7/20272; B33Y 50/02; G05B 19/4099; G05B 2219/49007; G06F 2200/201; G05B 2219/35134

(57) ABSTRACT

Example implementations relate to an integrated liquid cooling of a server system. For example, a method for integrated liquid cooling of a server system can include creating a liquid cooling component that includes creating a three dimensional (3D) design based on a server system, where the 3D design includes customized angle geometry. Further, the method for integrated liquid cooling of a server system can include forming the liquid cooling component based on the 3D design, where the liquid cooling component includes a plurality of liquid flow passages for delivering cooling resources to the server system, and delivering the cooling resources to the server system via the liquid cooling component.

### BACKGROUND

A server system responds to requests across a network to provide and/or help provide a service. Server systems can have temperature limitations. For example, a server system can malfunction if the temperature of the server system reaches or exceeds a threshold temperature. Heat from the use of the server system can be controlled using cooling systems. Examples of cooling systems include air and liquid cooling systems. Servers may be cooled, for example, using many individual components. Liquid cooling may sometimes include plumbing connections, such as tubing.

### BRIEF DESCRIPTION OF THE DRAWINGS

FIG. 1 illustrates two perspective views of an example of an integrated liquid cooling component, according to the present disclosure;

FIG. 2 illustrates an example method for integrated liquid cooling of a server system, according to the present disclosure;

FIG. 3 illustrates a block diagram of an example of integrated liquid cooling of a server system according to the present disclosure; and

FIG. 4 illustrates an example of a system for integrated liquid cooling of a server system, according to the present disclosure.

### DETAILED DESCRIPTION

As server system densities have increased, so too have the challenges of cooling and/or heat rejection for server systems. Liquid cooling of a server system can be more efficient than air-cooling systems. Air-cooling systems can use heat sinks and fans to remove “waste” heat from the system. Liquid cooling can bring a cooling agent directly to the server system to reduce heat. For example, liquid-cooled plates can be placed on top of components, such as a central processing units (CPUs) or a graphic processing units (GPUs), dual in-line memory modules (DIMMs), and actively deliver liquid directly onto the servers.

Liquid cooling traditionally includes a series of plumbing connections, fittings, tubes, and liquid interfaces associated with the server system. Traditional components often incorporate copper, brass, or nylon components and/or fittings, such as plumbing trees, threaded fittings, and barbed fittings. As used herein, these traditional components are referred to as conventional components. Each one of the fittings may contribute to one or more material disconnects, which form potential leak points. Material disconnect is when a first material (e.g., component, threaded fitting, etc.) fails to form a complete seal with a second material. The failure to form a complete seal may cause a leak point.

When built from conventional components, the plumbing connections may have significant limitations associated with flow passage geometry. For example, the size and shape of conventional connections may not form the most efficient design around and/or within a server system. Further, the multiple joint connections from the connections, fittings, and tubes form potential leak points due to corrosion and/or weak seals. As the liquid travels through the plumbing connections using conventional components, the risk of leakage of the liquid within the server system may increase.

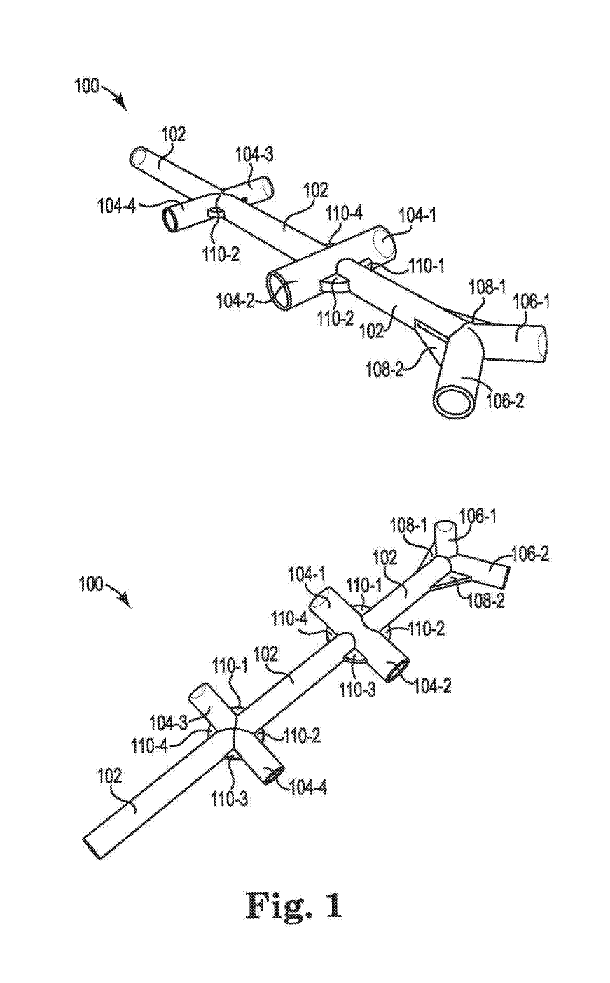

Liquid leakage from a cooling system can cause damage to the server system. For example, liquid leaks can cause a server system to malfunction and/or cause physical damage to equipment. To reduce potential leaks, a liquid cooling component can be created using a three-dimensional (3D) design that includes customized angle geometry based on a structure, organization, and/or layout of the server system. Customized angle geometry refers to custom (e.g., parametric) tube diameters, custom transition pieces, and split combinations. Custom transition pieces refer to components narrowing, bending, threading, and/or modification from one point in the liquid cooling component to a different point. A split combination refers to the different formations the liquid cooling component can include that direct and redirect fluid flow. For example, a split combination can include a horizontal or a Y-shaped split associated with a liquid cooling component, as discussed further in connection with FIG. 1.

The liquid cooling component can be formed using the 3D design and an additive manufacturing process and/or a monolithic process, such as a 3D-printer. The resulting liquid cooling component(s) can provide liquid flow passages of customizable shape and/or angle (e.g., user configurable). Liquid cooling components formed using 3D design and/or monolithic process can decrease the number of joint connects, and decrease potential failure (e.g., leak) points within the liquid cooling system.

Examples in accordance with the present disclosure can include a method of integrated liquid cooling of a server system. An example of method integrated liquid cooling of a server system can include creating a liquid cooling component. The liquid cooling component can be created using a 3D design based on a server system, where the 3D design includes customized angle geometry. The liquid cooling component can be formed based on the 3D design, where the liquid cooling component includes a plurality of liquid flow passages for delivering cooling resources to the server system. Cooling resources can include liquids, such as water, coolant, and/or chemicals, that can cool (e.g., absorb, dissipate heat, etc.) hardware components when in contact with a server system. Further, the method of integrated liquid cooling of a server system can include delivering the cooling resources to the server system via the liquid cooling component.

As used herein, a server system can refer to a rack server, a blade server, a server cartridge, a chassis, individual loads, CPUs, CPUs, and/or DIMMs. A rack server can include a computer that is used as a server and designed to be installed in a rack. A blade server can include a thin, modular electronic circuit board that is housed in a chassis and each blade is a server. A server cartridge, as used herein, can include a frame (e.g., a case) substantially surrounding a processing resource, a memory resource, and a non-volatile storage device coupled to the processing resource.

A chassis can include an enclosure, which can contain multiple blade servers and provide services such as power, cooling, networking, and various interconnects and management. A rack can include a frame (e.g., metal) that can contain a plurality of servers and/or chassis stacked one above another.

FIG. 1 illustrates two perspective views of an example of an integrated liquid cooling component, according to the present disclosure. As used herein, an integrated liquid cooling component refers to a cooling component having customized joints, angles, and/or liquid flow passages integrated into a single fabricated component. As illustrated by FIG. 1, liquid cooling component 100 can include a body 102. The body 102 can travel the length of the liquid cooling component 100 and liquid can flow through the body 102. For example, liquid cooling resources can flow from a first end of the body 102 to a second end of the body 102,

The body 102 can include liquid flow passages 104-1, 104-2, 104-3, 104-4, 106-1, and 106-2, referred to herein generally as 104, 106. The liquid flow passages are branches from the body 102 that allow liquid flow, such as liquid cooling resources, to travel to areas beyond the body 102,

The liquid flow passages 104, 106, (e,g,, 104-1, 104-2, 104-3, 104-4, 106-1, and 106-2) can be in a number of different geometric shapes. For examples, the liquid flow passage 104 can be in a horizontal geometric shape as illustrated at 104. Additionally, or alternatively, the liquid flow passage 106 can be in a Y-shaped geometry as illustrated at 106.

Liquid flow passages can be a horizontal passage. For example, the liquid flow passage 104 can be a “T” shape relative to the body 102 of the liquid cooling component 100. The formation of the horizontal or T shape liquid flow passage can include reinforcement 110. That is, the liquid flow passage 104 can extend in a direction orthogonal to the body 102 of the liquid cooling component 100. The reinforcement 110 is a portion of material placed in the areas of with an increased liquid flow passage diameter and/or transitions. The reinforcement 110 can provide external structure reinforcement and/or mechanical support such that the liquid passage structure is stable and not under stress and/or sudden intense pressure. For example, reinforcement 110 can provide structural support (e.g., mechanical) for the liquid flow passage (e.g., 104, 106) when the diameters of the liquid flow passage increases. That is, an increased liquid flow passage diameter that may have an increase of liquid flow can have an associated reinforcement to provide additional structural support.

Reinforcement 110-1, 110-2, 110-3, 110-4 (referred to herein generally as 110) can flank liquid flow passage 104 to provide structural support and/or mechanical support associated with the liquid flow passage 104. Although four (4) reinforcements 110 illustrated in FIG. 1 are flanking each liquid flow passage 104, examples are not so limited. For instance, liquid cooling component 100 may include a horizontal liquid flow passage 104 and an increased or decreased number of reinforcements 110 can flank each liquid flow passage 104. Additionally, while FIG. 1 illustrates each liquid flow passage 104 as having a same number of reinforcements 100, examples are not so limited and each liquid flow passage can have a different number of reinforcements 110.

Liquid flow passage 106 can be a “Y” shape within the body 102 of the liquid cooling component 100. The Y shape liquid flow passage can include a gradual (e.g., less than a 90 degree angle) angle or a sharp (e.g., more than a 90 degree angle) angle. Reinforcement 108-1, 108-2 (referred to herein generally as 108) can flank liquid flow passage 106 to provide structural support and/or mechanical support within the liquid flow passage 106. Although reinforcement 108 is illustrated in FIG. 1 as depicting 108-1 and 108-2, examples are not so limited. For instance, liquid cooling component 100 may include a Y-shape liquid flow passage 106 and an increased or decreased number of reinforcement 108 can be included and/or excluded (e.g., 0, 1, 2, 3, etc.).

In some examples, formation of the liquid cooling component can create the “T” and/or a “Y” intersection in a smaller space when compared to conventional components. That is, a 3D design that includes customized angle geometry can define the liquid flow passages. Customized angle geometry can include angles that are smaller and/or similar to the shape of the server system, as compared to conventional components. The plurality of liquid flow passages (e.g., 104, 106) can provide a custom configuration for liquid flow routing. That is, liquid flow can be routed based on a custom configuration associated with a server system. While FIG. 1 illustrates liquid flow passages in a horizontal and Y shaped geometry, examples are not so limited. The liquid flow passages can be in alternative geometrics than those illustrated and can be custom configurable (e.g., user configurable) based on the components and layout of the server system.

The liquid cooling component 100 and liquid flow passages 104,106 can be created from a single material and/or a plurality of materials. For example, the liquid component 100 can be created from plastic, metal, and/or ceramics, among others. The liquid component 100 can be created from the material in a single process, thereby eliminating joints and potential leak points.

In some examples, the formed liquid cooling component can exclude flexible tubing. For instance, forming customized angles via the monolithic process, as opposed to using the conventional components, can create a unique and/or geometric specific curve and/or angle to form around server components (e.g., CPUs, GPUs, DIMMs etc.) and provide cooling resources to cool the server system.

In some examples, the liquid cooling component 100 can be formed from a rigid material and an integrated flexible material. For example, a rigid material, such as ceramic can be formed around a flexible material, such as plastic. That is, a flexible material and a rigid material as a single assembly can be combined. For instance, a flexible plastic tube can be encased within a ceramic tube to form the liquid cooling component 100. For example, portions of the liquid cooling component 100 can be made from rigid materials while other portions can be made from flexible materials. This can be accomplished by using multiple material additive machining processes, such as dual filament 3D printers.

The materials used to form the liquid cooling component 100 can be created from a number of materials such that the number of materials reduce the overall weight associated with the integrated liquid cooling component 100. For example, conventional components may attach several different components with different sealants and/or threadings. Due to the number of components, extra length of tubing to form around server systems, and/or the type of sealant applied, the conventional components may be heavy. Creating a liquid cooling component via a single process with customizable geometric angles to form around a server system can reduce the overall amount of material, thereby decreasing the weight, as compared to conventional components.

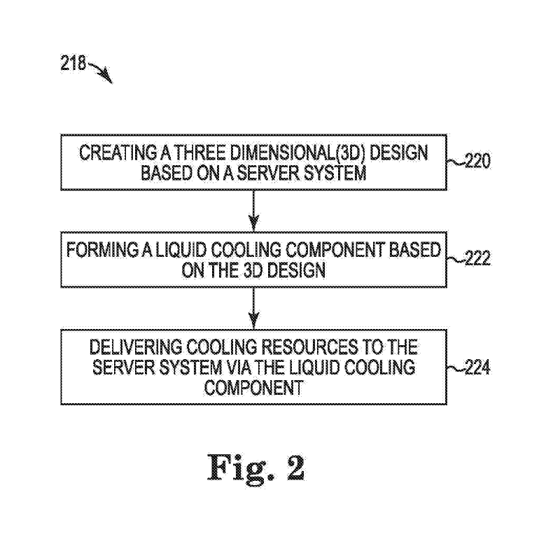

FIG. 2 illustrates an example method 218 for integrated liquid cooling of a server system, according to the present disclosure.

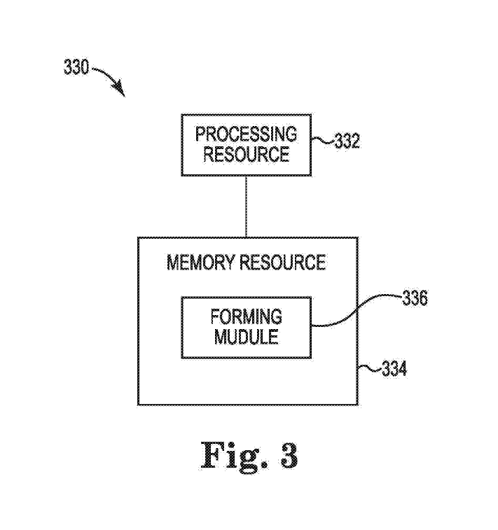

The method 218 can, in various examples, include a forming machine, such as a 3D printing device. A forming machine refers to a machine that includes forming elements that use material to create a physical model of a liquid cooling component from a set of instructions stored in a data store (e.g., memory, etc.), as will be discussed further in relation to FIG. 3.

Forming elements can be any suitable device/combination of devices to form liquid cooling components. For example, forming elements can, in some examples, form a liquid cooling component using additive manufacturing.

Additive manufacturing refers to addition of successive layers of material (e.g., layers having various shapes/specifications) to achieve a desired end product, such as a liquid cooling component. However, the present disclosure is not so limited. That is, the forming machine can form the liquid cooling component using various fabrication and/or extrusion manufacturing techniques (e.g., melting, ejection, solidification, etc.), rapid prototyping, freeform fabrication, and/or subtractive manufacturing (e.g., drilling, plasma/laser cutting, etc.), among other techniques suitable to form liquid cooling components.

In some examples, the method 218 can include, for example, creating a three dimensional (3D) design based on a server system 220. The 3D design can be created using a computer-aided design (CAD), such as digital designs.

As used herein, a 3D formation of a liquid cooling component refers to a 3D physical form of an integrated liquid cooling component (e.g., a liquid cooling system) having specifications (e.g., height, width, length, radius, volume, etc.) based on a particular server system. For example, the specifications of a liquid cooling component can be unique and based on a particular server system.

In some examples, the 3D design can include customized angle geometry. That is, the 3D design can include angles unique to a server system and/or components with angles that may not be traditionally available with conventional and/or pre-fabricated components. For example, a server system may have a plurality of CPUs, CPUs, and/or DIMMs. The 3D design can be customized such that the angle of the liquid cooling component form in accordance with the angles of the CPUs and CPUs,

In some examples, the method 218 can include forming the liquid cooling component based on the 3D design 222. The 3D design can be formed using a monolithic process, such as 3D printing. Forming the liquid cooling component can include creating the customized angle geometry and/or similar angles within the server system. That is, in some instances, the liquid cooling component can include a plurality of liquid flow passages for delivering cooling resources to the server system.

Forming the liquid cooling component, in some examples, can include forming seamless connections using customized internal barbs, ribs, threading, and/or a-ring seal structures. For example, rather than connect several components together (e.g., using a sealant) to form a complex cooling component, customized components can be formed for a seamless connection. That is, a monolithic process can create customized components to connect seamlessly, thereby reducing failure points (e.g., potential leaks).

Some examples of a liquid cooling component can include printing a flow structure onto the liquid cooling component to indicate liquid flow. That is, signs, symbols, and/or words can be printed onto the liquid cooling component during formation to indicate the direction of liquid flow. The printed flow structure can reflect a flow diagram.

The method 218 can include, in some examples, delivering the cooling resources to the server system via the liquid cooling component 224. That is, a customized liquid cooling component can be created that can be unique to a particular server system, to deliver cooling resources to the server system (e.g., CPUs, CPUs, DIMMS, racks, chassis, etc.).

FIG. 3 illustrates a block diagram of an example of integrated liquid cooling of a server system according to the present disclosure. As mentioned previously, the method for integrated liquid cooling of a server system described in FIG. 2, can, in various examples, include a forming machine, such as a 3D printing device. A forming machine refers to a machine that includes forming elements that use material to create a physical model of a liquid cooling component from a set of instructions stored in a data store (e.g., memory, etc.).

In various examples, the liquid cooling component can be based on the information associated with a server system. For example, a forming machine can form a 3D liquid cooling component unique to a layout associated with the server system.

The forming machine can include a processing resource 332 and a memory resource 334. Memory resource 334 can be any type of storage medium that can be accessed by the processing resource 332 to perform various examples of the present disclosure (e.g., form a liquid cooling component, etc.). For example, memory resource 334 can be a non-transitory forming machine readable medium having forming machine readable instructions (e.g., forming machine program instructions, machine readable instructions, computer readable instructions, etc.) and data items stored thereon.

In some examples, the memory resource 334 may be a non-transitory storage medium and/or a non-transitory machine readable medium, where the term “non-transitory” does not encompass transitory propagating signals. In some examples, the memory resource 334 can include one or more computing modules to perform particular actions, tasks, and functions of the forming machine.

As illustrated in FIG. 3, forming module 336 can include instructions executable by the processing resource 332 to form a liquid cooling component. That is, the forming module 336 can include the instructions to form the liquid cooling component using the 3D design based on the server system. As used herein, a computing module (e.g., forming module 336) can include program code, e.g., computer executable instructions, hardware, firmware, and/or logic. But a computing module at least includes instructions executable by the processing resource 332, e.g., in the form of modules, to perform particular actions, tasks, and functions described in more detail herein in reference to FIGS. 1, 2, and 4.

Memory resource 334 can be volatile or nonvolatile memory. Memory resource 334 can also be removable (e.g., portable) memory, or non-removable (e.g., internal) memory. For example, memory resource 334 can be random access memory (RAM) (e.g., dynamic random access memory (DRAM) and/or phase change random access memory (PCRAM)), read-only memory (ROM) (e.g., electrically erasable programmable read-only memory (EEPROM) and/or compact-disc read-only memory (CD-ROM)), flash memory, a laser disc, a digital versatile disc (DVD) or other optical disk storage, and/or a magnetic medium such as magnetic cassettes, tapes, or disks, among other types of memory.

The memory resource 334 can include forming machine readable instructions capable of being executed by the processing resource 332 to carry out the functions as described herein. In some examples, some or all of the functions are carried out via hardware in lieu of a processing resource 332-based system. In some examples, memory resource 334 can, in addition to the memory located in the forming machine or alternatively, be located internally within another computing resource (e.g., enabling computer readable instructions to be downloaded over the Internet or another wired or wireless connection).

The processing resource 332 executes instructions, such as forming machine readable instructions, and can, in some examples, be utilized to control the operation of the entire forming machine. The processing resource 332 can include a control unit that organizes data and program storage in memory and transfers data and/or other information between the various portions of the forming machine and/or other electronic devices.

Although the forming machine can contain a single processing resource 332, the disclosed example also applies to devices that may have multiple processing resources 332 with some or all performing different functions and/or in different ways. The forming machine readable instructions can, for example, include a number of programs such as the applications (e.g., software objects and/or modules, among others). The data items, such as information associated with a liquid cooling component and/or an electronic model, can be used (e.g., analyzed by) the forming machine readable instructions during their execution.

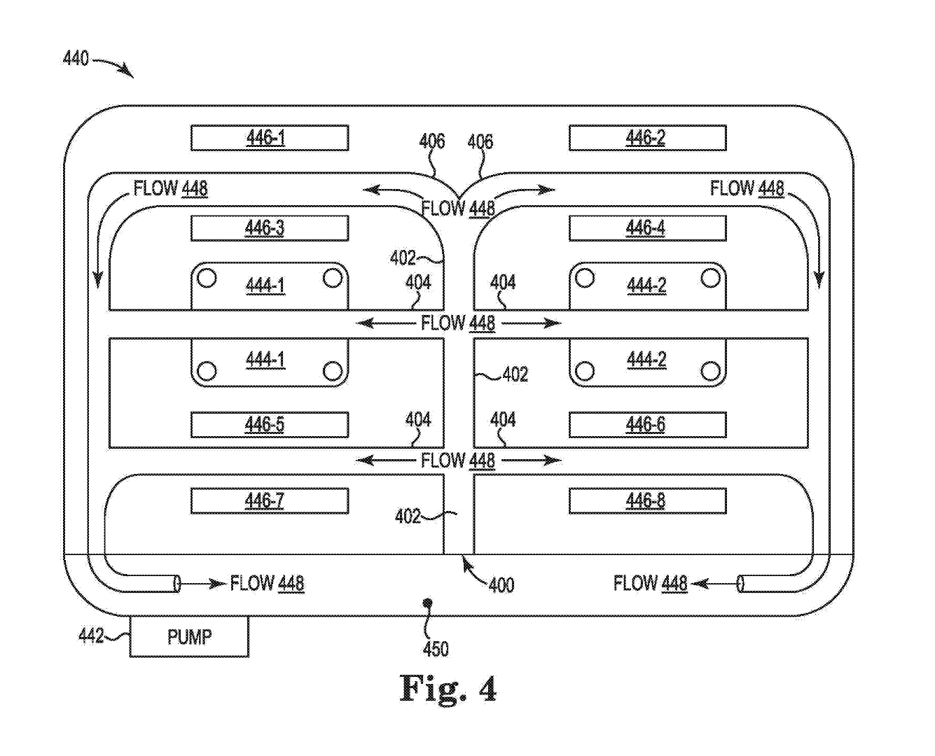

FIG. 4 illustrates an example of a system for integrated liquid cooling of a server system, according to the present disclosure.

As illustrated in FIG. 4, server system 440 utilizes a liquid cooling component 400. Liquid cooling component 400 operates analogous to liquid cooling component 100, as described in FIG. 1. For instance, the liquid cooling component can have a custom angle geometry formation based on a server system. As previously discussed in connection with FIGS. 1 and 2, the custom angle geometry can form a plurality of liquid flow passages on the liquid cooling component.

Server system 440 illustrates a server system including, for example, GPUs, CPUs 444-1, 444-2 (referred to generally as 444), and a DIMMs 446-1, 446-2, 446-3, 446-4, 446-5, 446-6, 446-7, 446-8 (referred to generally as 446). The liquid cooling component 400 can be created and formed based on the specific server system 440 architecture. That is, the liquid cooling component 440 can be created and formed based on the features (e.g., servers, CPU, GPU, etc.) within the server system 440.

The liquid cooling component 400 can be placed in and/or on the server system to deliver cooling resources to reduce temperature and/or heat buildup. The body 402 of the liquid cooling component can extend to the height and/or width of the server system 440. For example, the body 402 of the liquid cooling component can extend vertically and/or horizontally based on the particular server system. From the body 402, liquid flow passages 404, 406 branch out, for example, to form in and/or around the CPUs 446.

The liquid cooling component can include branches 438 from the flow passages 404, 406 to route cooling resources to the server system 440. That is, branches 438 extend from the body 402 and the flow passages 404, 406 as a single assembly based on a particular server system 440. For example, cooling resources can flow from the body 402, through the flow passage 404, and through the branching 438 which is placed among the CPU 444. The cooling resources flowing through the branches 438 located in and/or on the CPU 444 can deliver cooling resources to decrease the temperature of the CPU 444. The liquid cooling component 400 can also be formed to travel through branches 438 between a plurality of DIMMs 446 and deliver the cooling resources.

In some examples, once the cooling resources within the liquid cooling component have flowed through the body 402, flow passages 404, 406, and/or the branches 438, the cooling resources can flow into the manifold 450 for collection. The manifold 450 can collect the cooling resource and either dispose of the cooling resources or replenish the cooling resources to repeat the cooling process.

In some examples, the liquid cooling component can have a pump 442 integrated within the liquid cooling component to deliver cooling resources to the server system via the plurality of liquid flow passages. That is, a pump 442 can force cooling resources through the body 402, liquid flow passages 404, 406, and the branches 438 to deliver cooling resources to the sever system.

In the present disclosure, reference is made to the accompanying drawings that form a part hereof, and in which is shown by way of illustration how a number of examples of the disclosure may be capable of being practiced. These examples are described in sufficient detail to enable those of ordinary skill in the art to practice the examples of this disclosure, and it is to be understood that other examples may be capable of being used and that process, electrical, and/or structural changes may be capable of being made without departing from the scope of the present disclosure.

The figures herein follow a numbering convention in which the first digit corresponds to the drawing figure number and the remaining digits identify an element or component in the drawing. Elements shown in the various figures herein may be capable of being added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense.

Further, as used herein, “a” or “a number of” something can refer to one or more such things. For example, “a number of widgets” can refer to one or more widgets. Also, as used herein, “a plurality of” something can refer to more than one of such things.

The above specification, examples and data provide a description of the method and applications, and use of the system and method of the present disclosure. Since many examples may be capable of being made without departing from the spirit and scope of the system and method of the present disclosure, this specification merely sets forth some of the many possible example configurations and implementations.

What is claimed is:

1. A method for integrated liquid cooling of a server system, comprising:
creating a liquid cooling component, including:
creating a three dimensional (3D) design based on a server system, wherein the 3D design includes customized angle geometry; and
forming the liquid cooling component based on the 3D design, wherein the liquid cooling component includes a plurality of liquid flow passages for delivering cooling resources to the server system; and
delivering the cooling resources to the server system via the liquid cooling component.

2. The method of claim 1, wherein the liquid cooling component is formed using a monolithic process.

3. The method of claim 1, wherein forming the liquid cooling component includes combining a flexible material and a rigid material as a single assembly.

4. The method of claim 1, wherein forming the liquid cooling component includes using a single material to define the plurality of liquid flow passages and a body of the liquid cooling component.

5. The method of claim 1, wherein forming the liquid cooling component includes forming mounting flanges to secure a liquid flow passage among the plurality of liquid flow passages to a site on the server system.

6. The method of claim 1, further including providing structural support for the plurality of liquid flow passages using a plurality of reinforcements associated with the flow passages.

7. The method of claim 1, wherein forming the liquid cooling component includes forming a body and liquid flow passages having seamless joint connections.

8. The method of claim 1, further comprising forming a plurality of liquid cooling components, and connecting the plurality of liquid cooling components to create an integrated liquid cooling system.

9. The method of claim 1, wherein forming the liquid cooling component includes using a 3D printer.

10. A non-transitory computer readable medium storing instructions executable by a processing resource to:
create a three dimensional (3D) liquid cooling component design based on a server system, wherein the 3D liquid cooling component design includes customized angle geometry;
form the liquid cooling component based on the 3D liquid cooling component design, wherein the formed liquid cooling component includes a plurality of liquid flow passages for delivering cooling resources; and
deliver cooling resources through the plurality of liquid flow passages to a server system.

11. The medium of claim 10, wherein the customized angle geometry includes custom tube diameters, custom transition pieces, and split combinations.

12. The medium of claim 10, wherein the instructions to form the liquid cooling component includes seamless connections between each of the plurality of liquid flow passages and a body of the liquid cooling component, internal barbs, ribs, threading, and o-ring seal structures.

13. An integrated liquid cooling system, comprising:
a liquid cooling component with a custom angle geometry formation based on a server system, wherein the custom angle geometry defines a plurality of liquid flow passages for delivering cooling resources to the server system; and
a pump integrated within the liquid cooling component to force the cooling resources to the server system via the plurality of liquid flow passages.

14. The system of claim 13, wherein the liquid cooling component extends the entire height of the server system and is formed based on an architecture of components in the server system.

15. The system of claim 13, wherein each of the plurality of liquid flow passages are of a specified height, width, length, and radius based on the server system.
